(19) United States
(12) Patent Application Publication
(10) Pub. No.: US 2014/0374761 A1
(43) Pub. Date: Dec. 25, 2014

(54) Structure, Method for Manufacturing Structure, and illuminating structure of Thin Film Transistor

(71) Applicant: WISTRON CORP., New Taipei City (TW)

(72) Inventors: Yi-Kai WANG, NEW TAIPEI CITY (TW); Tarng-Shiang HU, NEW TAIPEI CITY (TW); Chi-Jen KAO, NEW TAIPEI CITY (TW)

(73) Assignee: WISTRON CORP., New Taipei City (TW)

(21) Appl. No.: 14/246,155

(22) Filed: Apr. 7, 2014

(30) Foreign Application Priority Data
Jun. 24, 2013 (TW) 102122394

(51) Int. Cl. H01L 33/52; H01L 29/786; H01L 29/66

(52) U.S. Cl. CPC H01L 33/52; H01L 29/66742; H01L 29/786
USPC 257/66; 438/151

(57) ABSTRACT

A structure, a method for manufacturing a structure, and an illuminating structure of a thin film transistor are disclosed. In the method, a substrate is provided, and a patterned first conductor layer is formed on the substrate. A patterned semiconductor layer, a patterned insulation layer, and a patterned second conductor layer are formed after forming the patterned first conductor layer, in which the patterned insulation layer contacts with the patterned second conductor layer. A first permeation barrier layer which covers the patterned second conductor layer and the patterned insulation layer is formed.

### RELATED APPLICATIONS

This application claims priority to Taiwanese Application Serial Number 102122394, filed Jun. 24, 2013, which is herein incorporated by reference,

### BACKGROUND

1. Field of Disclosure

The present disclosure relates to a thin film transistor structure. More particularly, the present disclosure relates to a thin film transistor structure applied on a display.

2. Description of Related Art

In an organic thin film transistor element, the organic semiconductor material thereof is apt to suffer from moisture. When the moisture enters, a threshold voltage of the element shifts, which reduces the driving current and increases the sub-threshold slope. As such, the reliability and performance of the organic thin film transistor element are deteriorated, and product application is thus limited. A plenty of package processes are provided for addressing issues of the moisture permeation. Generally, in a display manufacturing process (especially the Electronic paper or the self-illuminating display), package processes for manufacturing the moisture barrier layer are limited by the availability of elements (including both active elements and displaying mediums). Both upper and lower substrates have good moisture barrier properties; however, side frames are sealed with sealants which are resistant to the moisture or by directly attaching of the substrates. Due to limitations of package structure of the side frames and the material property, the moisture is easy to permeate into the display through the package structure of the side frames. The permeation is getting even worse in the manufacturing of the flexible display, in that the flexible sealant material for the flexible display has less moisture resistance than that of the conventional sealant material. Some of the flexible sealant materials are even incompatible with the materials of the flexible substrate, which reduce adhesive capability of the sealant materials and worsen the problem of the moisture permeation.

### SUMMARY

According to one embodiment of the present disclosure, a method for manufacturing a thin film transistor structure is disclosed. In the method, a substrate is provided, a patterned first conductor layer is formed on the substrate. A patterned semiconductor layer, a patterned insulation layer, and a patterned second conductor layer are formed after the forming of the patterned first conductor layer, in which the patterned insulation layer contacts with the patterned second conductor layer. A first permeation barrier layer which covers the patterned second conductor layer and the patterned insulation layer is formed.

According to another embodiment of the present disclosure, a structure of a thin film transistor is disclosed. The structure of the thin film transistor includes a patterned first conductor layer, a patterned semiconductor layer, a patterned insulation layer, a patterned second conductor layer, and a first permeation barrier layer. The patterned first conductor layer is disposed on the substrate. The patterned semiconductor layer, the patterned insulation layer, and the patterned second conductor layer are disposed on the patterned first conductor layer, in which the patterned insulation layer contacts with the patterned second conductor layer. The first permeation barrier layer covers the patterned second conductor layer and the patterned insulation layer.

According to still another embodiment of the present disclosure, an illuminating structure of a thin film transistor is disclosed. The illuminating structure of the thin film transistor includes a patterned first conductor layer, a patterned semiconductor layer, a patterned insulation layer, a patterned second conductor layer, a first permeation barrier layer, and an illuminating layer. The patterned first conductor layer is disposed on a substrate. The patterned semiconductor layer, the patterned insulation layer, and the patterned second conductor layer are disposed on the patterned first conductor layer, in which the patterned insulation layer contacts with the patterned second conductor layer. The first permeation barrier layer covers the patterned second conductor layer and the patterned insulation layer, in which the first permeation barrier layer is passed through by a contact window. The illuminating layer is filled in the contact window.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A to FIG. 1G are cross-sectional views of a structure of a thin film transistor during a manufacturing process according to a first embodiment of the present disclosure; and

FIG. 2A to FIG. 2B are cross-sectional views of a structure of a thin film transistor during a manufacturing process according to a second embodiment of the present disclosure;

FIG. 3A to FIG. 3F are cross-sectional views of a structure of a thin film transistor during a manufacturing process according to a third embodiment of the present disclosure;

FIG. 4A to FIG. 4G are cross-sectional views of a structure of a thin film transistor during a manufacturing process according to a fourth embodiment of the present disclosure;

FIG. 5A to FIG. 5H are cross-sectional views of an illuminating structure of a thin film transistor during a manufacturing process according to a fifth embodiment of the present disclosure; and

FIG. 6A to FIG. 6H are cross-sectional views of an illuminating structure of a thin film transistor during a manufacturing process according to a sixth embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The structure of the thin film transistor and the method for manufacturing thereof of the following embodiments integrate a permeation barrier layer into the current manufacturing process, the inner materials can be directly packaged within the structure of the thin file transistor, therefore, the side package structure is not easily cracked or leaked, which effectively prevents damages caused by moistures.

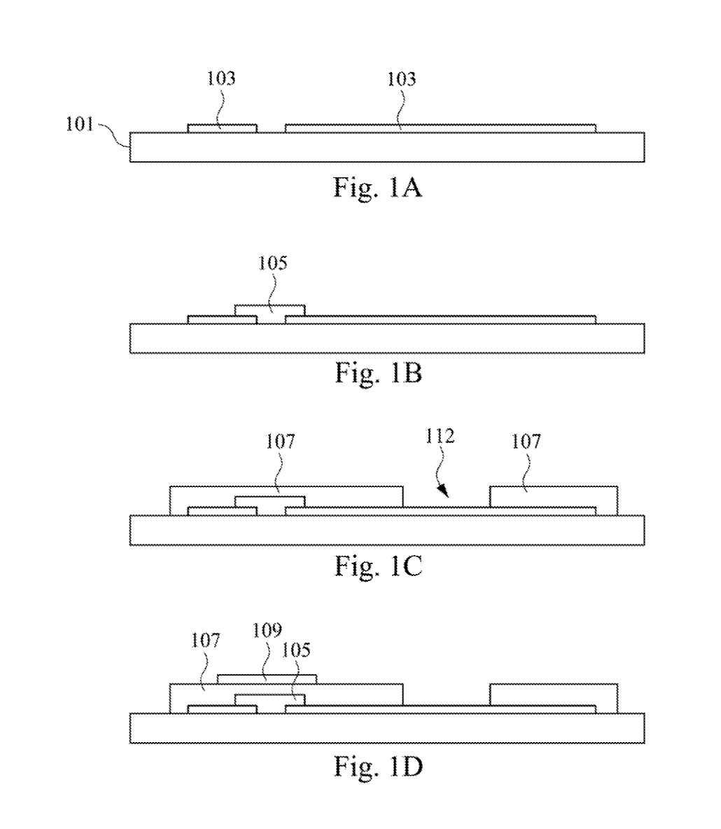

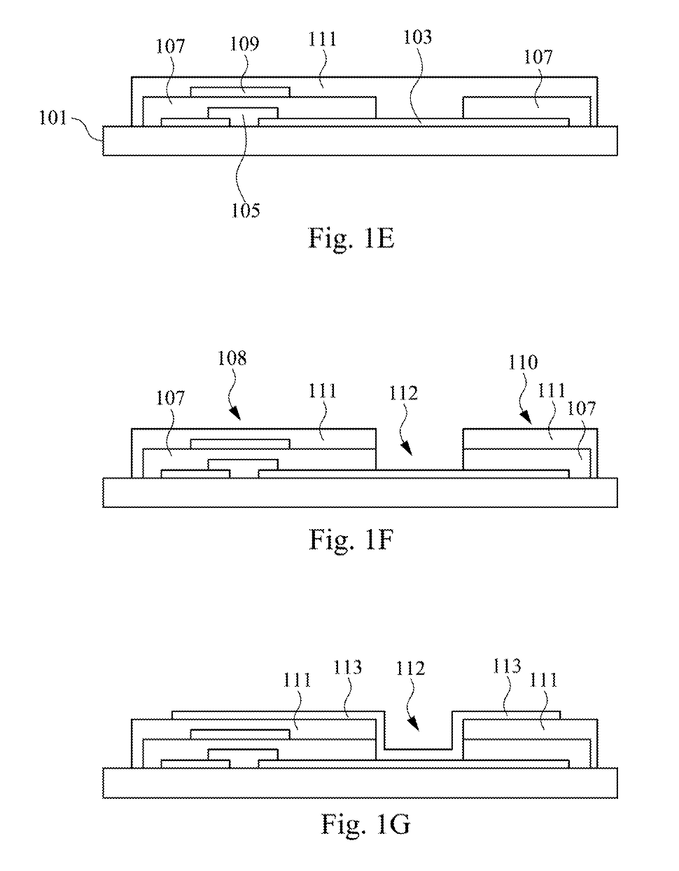

FIG. 1A to FIG. 1G are cross-sectional views of a structure of a thin film transistor during a manufacturing process according to a first embodiment of the present disclosure. The thin film transistor can be an inorganic thin film transistor, an organic thin film transistor, an element of a flexible display (such as an electronic paper element), or other organic semiconductor material. In the method, a substrate 101 is first provided, and a patterned first conductor layer 103 (FIG. 1A) and a patterned semiconductor layer 105 (FIG. 1B) in contact with the patterned first conductor layer 103 are formed on the substrate 101. After the forming of the patterned semiconductor layer 105, a patterned insulation layer 107 is formed; particularly, a permeation barrier layer can be taken as the patterned insulation layer 107. The patterned insulation layer 107 is subsequently etched to produce a contact window 112 (FIG. 1C), and a patterned second conductor layer 109 is formed thereon (FIG. 1D).

A first permeation barrier layer 111 is subsequently formed on the patterned second conductor layer 109 (FIG. 1E), and the first permeation barrier layer 111 covers the patterned second conductor layer 109 and the patterned insulation layer 107, such that the patterned second conductor layer 109 and the patterned insulation layer 107 are not exposed to moisture and can be prevented from being eroded by moisture. The first permeation barrier layer 111 can be a multi-layers structure or an organic and inorganic compound structure and can be made of Al₂O₃, Al₂O₃, or ZrO₂. The permeation barrier layer 111 can be manufactured through a Chemical Vapor Deposition (CVD) process or an Atomic Layer Deposition (ALD) process. Specifically, the permeation barrier layer 111 can be manufactured through a Sheet to Sheet process, a Roll to Roll process, or a Reel to Reel process.

A thickness of the first permeation barrier layer 111 ranges from 1 nm to 100 nm, the Water Vapor Transmission Rate of the first permeation barrier layer 111 ranges from 10E-2 g/m² day to 10E-6 g/m² day, and the Oxygen Transmission Rate of the first permeation barrier layer 111 ranges from 10E-2 cc/m² day to 10E-5 cc/m² day. The manufacture temperature of the first permeation barrier layer 111 ranges from 120° C. to 160° C., and the preferred temperature is 125° C. and 150° C. The forming pressure is less than 1 Torr, and 1.2 Å (Angstrom) is formed for each cycle.

The first permeation barrier layer 111 is etched to extend the contact window 112 (FIG. 1F) after it has been formed, and the contact window 112 separates the first permeation barrier layer 111 and the patterned insulation layer 107 into a first region 108 and a second region 110. The patterned third conductor layer 113 is alternatively disposed on the first permeation barrier layer 111 (FIG. 1G) and enters the contact window 112 to cover a surface of the contact window 112. The patterned third conductor layer 113 is not necessary but depends on the actual requirement.

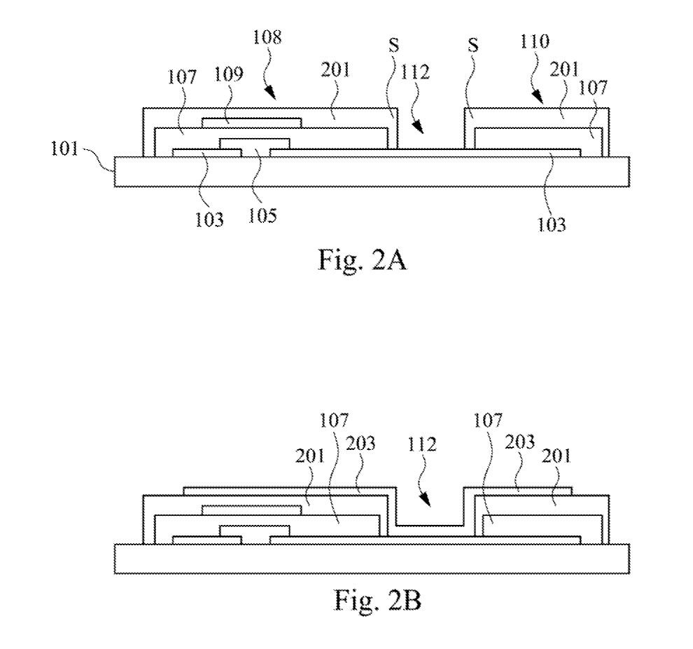

FIG. 2A to FIG. 2B are cross-sectional views of a structure of a thin film transistor during a manufacturing process according to a second embodiment of the present disclosure. The same reference number in this second embodiment and in the aforesaid first embodiment represent the same material layer or the same structure, therefore, structures of the substrate 101, the patterned first conductor layer 103, the patterned semiconductor layer 105, the patterned insulation layer 107, and the patterned second conductor layer 109 have been described as above. Particularly, the structures of the first permeation barrier layer 201 and the patterned third conductor layer 203 are different from those in the First embodiment. In this second embodiment, the first permeation barrier layer 201 in region S is not etched out but kept (FIG. 2A), and the first permeation barrier layer 201 in region S covers sides of the patterned insulation layer 107 to prevent patterned insulation layer 107 from being exposed to outside. The patterned third conductor layer 203 is disposed on surfaces of the first permeation barrier layer 201 and the patterned first conductor layer 103 and is not in contact with the patterned insulation layer 107.

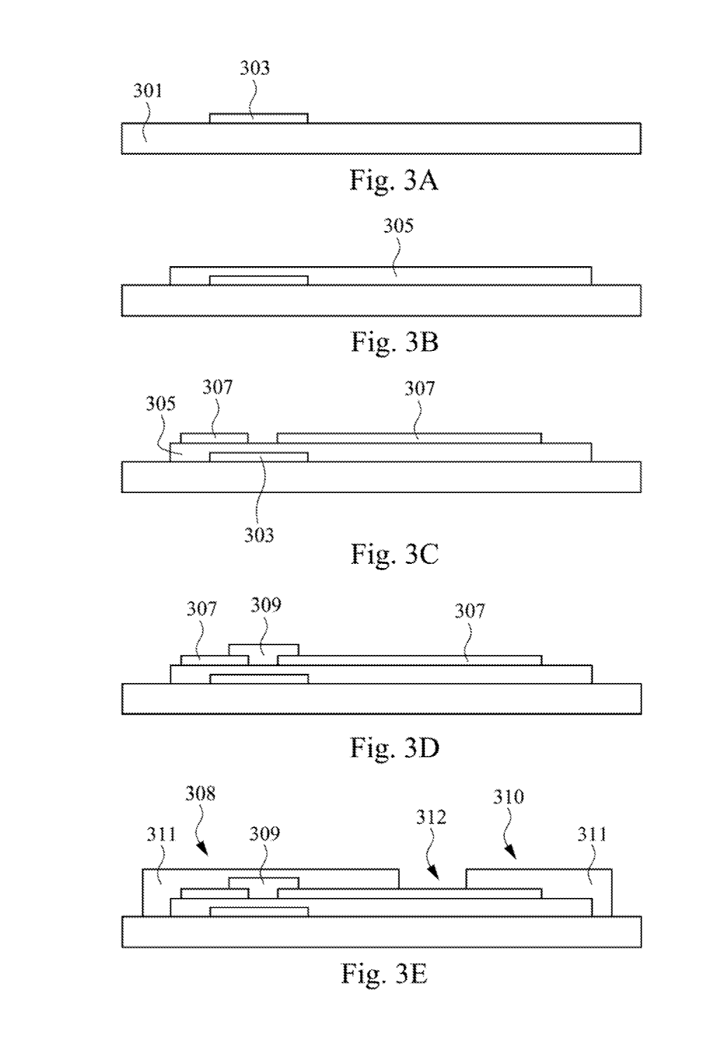

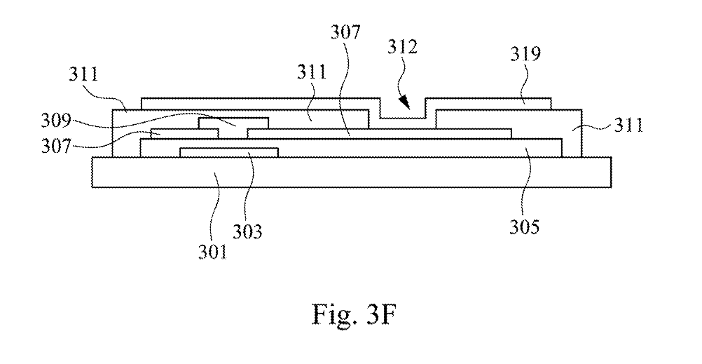

FIG. 3A to FIG. 3F are cross-sectional views of a structure of a thin film transistor during a manufacturing process according to a third embodiment of the present disclosure. In the method, a substrate 301 is first provided, and a patterned first conductor layer 303 (FIG. 1A) is formed on the substrate 301 (FIG. 3A). The patterned insulation layer 305 is subsequently formed (FIG. 3B), in which a permeation barrier layer can be used as the patterned insulation layer 305. The forming of the patterned second conductor layer 307 is after the forming of the patterned first conductor layer 303 and the patterned insulation layer 305 (FIG. 3C). The patterned insulation layer 305 covers the patterned first conductor layer 303 to insulate two conductor layers in order to prevent the current leakage.

The patterned semiconductor layer 309 is disposed on the patterned second conductor layer 307 (FIG. 3D), this patterned semiconductor layer 309 contacts with the patterned second conductor layer 307. Next, a first permeation barrier layer 311 which covers the patterned semiconductor layer 309 is formed on the patterned semiconductor layer 309, and the patterned semiconductor layer 309 is not exposed to outside. Therefore, the patterned semiconductor layer 309 and the material layers under there are protected from being attacked by the moisture. The material, the thickness, and the forming method of the first permeation barrier layer 311 in this embodiment is the same as those of the first permeation barrier layer 111 in the previous embodiment.

The first permeation barrier layer 311 is etched to form a contact window 312 (FIG. 3E), and this contact window 312 separates the first permeation barrier layer 311 into a first region 308 and a second region 310. The patterned third conductor layer 319 enters the contact window 312 from the surface of the first permeation barrier layer 311 and contact with the patterned second conductor layer 307.

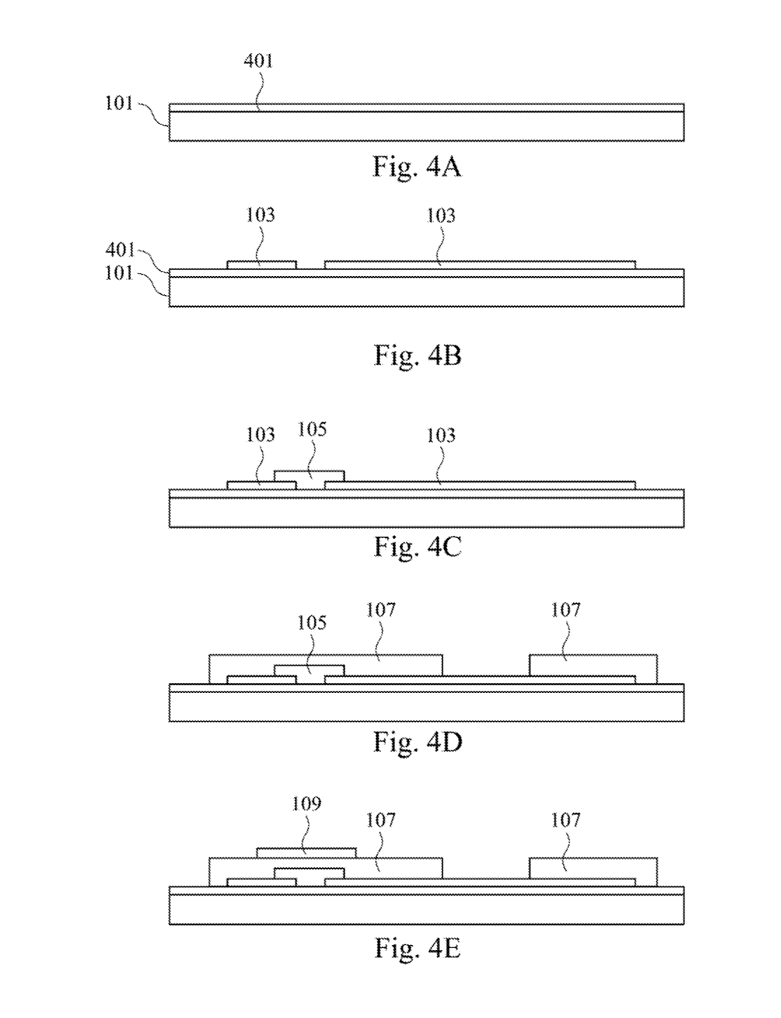

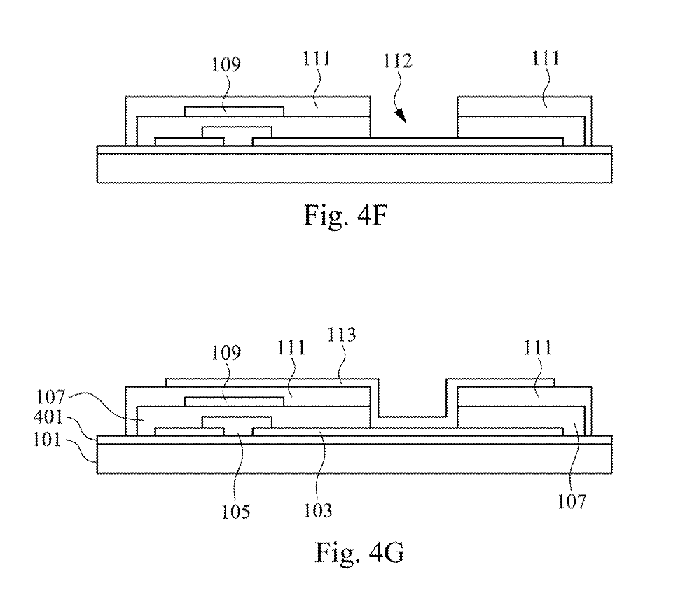

FIG. 4A to FIG. 4G are cross-sectional views of a structure of a thin film transistor during a manufacturing process according to a fourth embodiment of the present disclosure. In this fourth embodiment, the structures and the manufacturing processes of the substrate 101 (FIG. 4A), the patterned first conductor layer 103 (FIG. 4B), the patterned semiconductor layer 105 (FIG. 4C), the patterned insulation layer 107 (FIG. 4D) (can be implemented with a permeation barrier layer), the patterned second conductor layer 109 (FIG. 4E), and the first permeation barrier layer 111 (FIG. 4G) are same to those described in the first embodiment (FIG. 1A to FIG. 1G); however, an additional isolation film layer 401 (FIG. 4A) is disposed on the substrate 101 in this fourth embodiment, which forms a top gas barrier insulator.

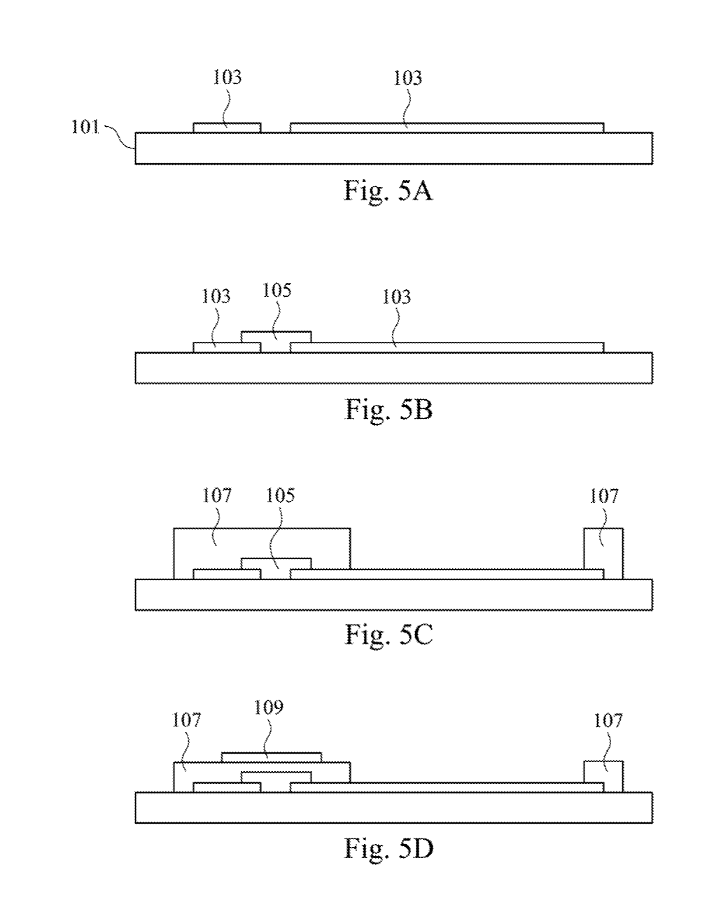

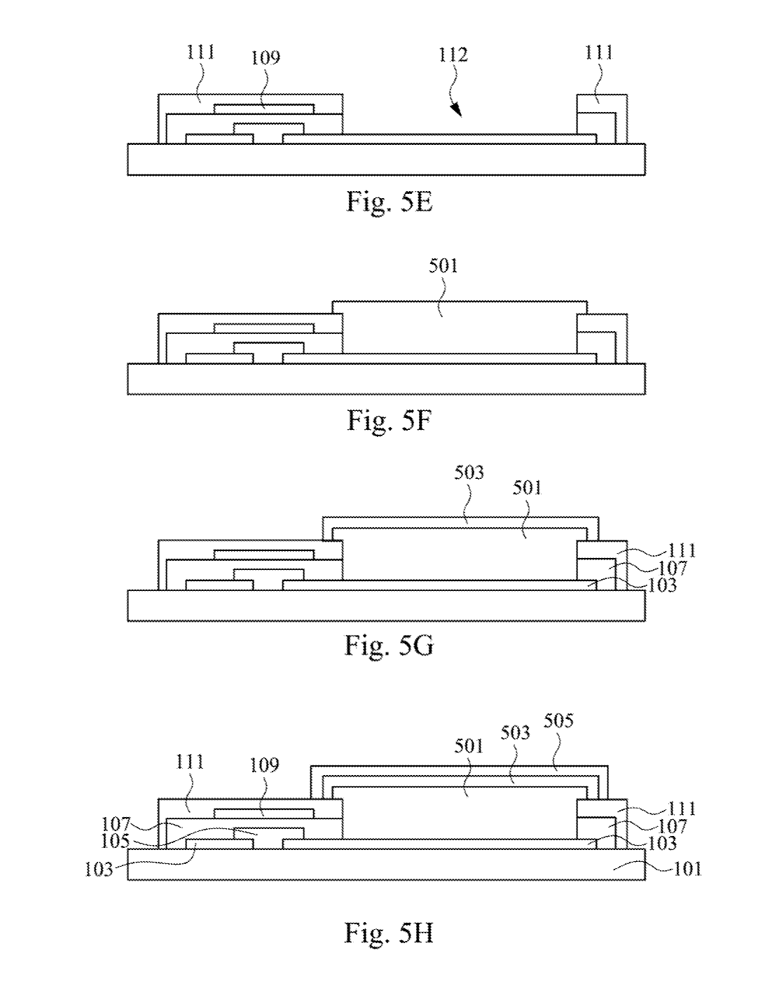

FIG. 5A to FIG. 5H are cross-sectional views of an illuminating structure of a thin film transistor during a manufacturing process according to a fifth embodiment of the present disclosure. Similar to the first embodiment shown in FIG. 1A to FIG. 1F, the illuminating structure of the thin film transistor also includes the substrate 101, the patterned first conductor layer 103 (FIG. 5A), the patterned semiconductor layer 105 (FIG. 5B), the patterned insulation layer 107 (FIG. 5C), the patterned second conductor layer 109 (FIG. 5D), the first permeation barrier layer 111, and the contact window 112 (FIG. 5E). In addition to those layers, an additional illuminating layer 501 is formed after the forming of the first permeation barrier layer 111 and is formed before the forming of the patterned third conductor layer 503 (FIG. 5F).

Specifically, the illuminating layer 501 passes through the contact window 112 and contacts with the patterned first conductor layer 103, and the patterned third conductor layer 503 is disposed on the illuminating layer 501. After the disposing of the patterned third conductor layer 503, a second permeation barrier layer 505 is disposed on the patterned third conductor layer 503.

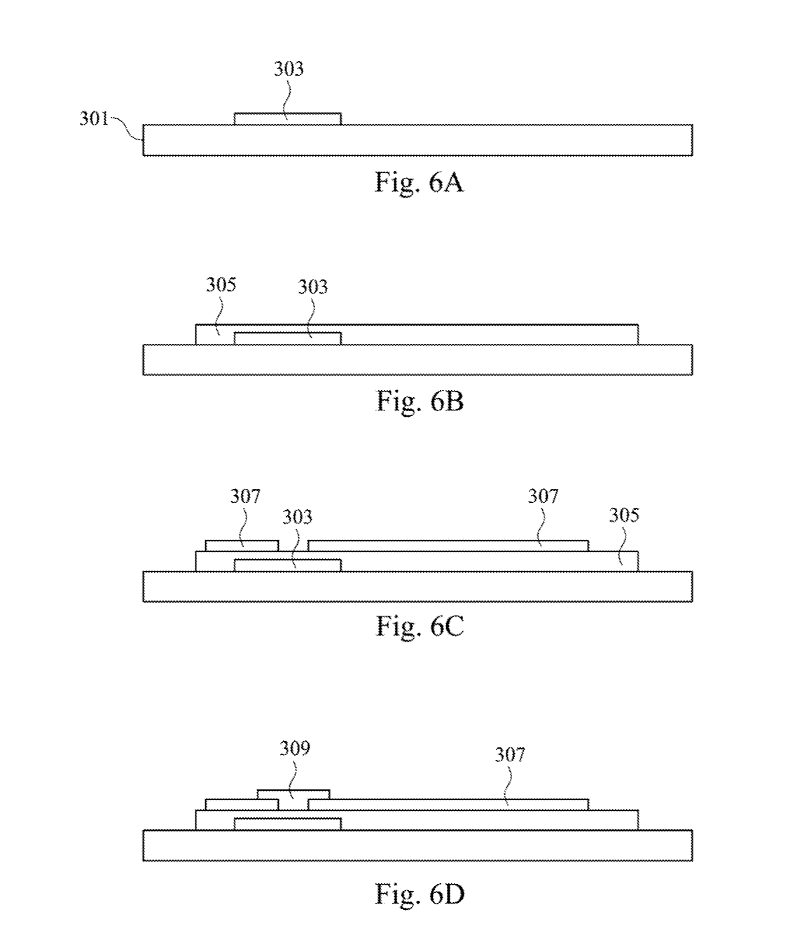

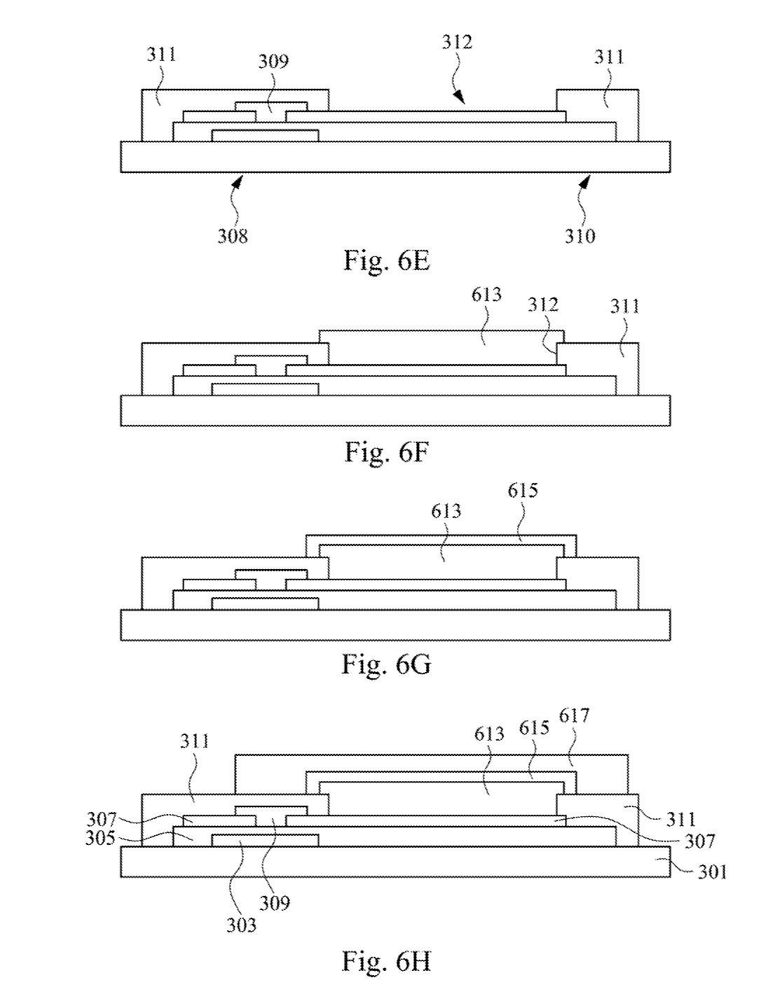

FIG. 6A to FIG. 6H are cross-sectional views of an illuminating structure of a thin film transistor during a manufacturing process according to a sixth embodiment of the present disclosure. Similar to the third embodiment shown in FIG. 3A to FIG. 3E, the illuminating structure of this embodiment also includes the substrate 301, the patterned first conductor layer 303 (FIG. 6A), the patterned insulation layer 305 (FIG. 6B), the patterned second conductor layer 307 (FIG. 6C), the patterned semiconductor layer 309 (FIG. 6D), the first permeation barrier layer 311 (FIG. 6E), and the contact window 312. The illuminating layer 613 is disposed on the first permeation barrier layer 311 and is filled in the contact window 312 (FIG. 6F). Subsequently, a patterned third conductor layer 615 (FIG. 6G) and a second permeation barrier layer 617 are sequentially stacked on the illuminating layer 613, in which the patterned third conductor layer 615 covers the illuminating layer 613, and the second permeation barrier layer 617 covers the patterned third conductor layer 615 to prevent the patterned third conductor layer 615 from exposing to the moisture environment.

With the permeation barrier layer disposed through the atomic layer deposition process, the thin film transistor maintains the original properties when it has been tested under a 60° C., relative humidity 85% moisture environment for 480 hours. It can also be realized from the related testing that value of the water vapor transmission rate reduces if the permeation barrier layer is disposed. Furthermore, the water vapor transmission rate is reduced, and the moisture prevention effect is getting better if the permeation barrier layer is getting thicker. For example, when a thickness of the permeation barrier layer made of ALD Al₂O₃ is as thick as 10 nm, the water vapor transmission rate is less than 5×10⁻⁵ g/m² day.

The structure of the thin film transistor and the method for manufacturing thereof of above embodiments integrate a single permeation barrier layer or several permeation barrier layers into the current manufacturing process, which presents the side structures of the TFT from being damaged by the moisture. In addition, regions required packaging can be directly packed due to the compatibility of the packaging process and the TFT manufacturing process, which prevents the moisture from intrusion.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fail within the scope of the following claims.

What is claimed is:

1. A method for manufacturing a structure of a thin film transistor, comprising:
providing a substrate;
forming a patterned first conductor layer on the substrate;
forming a patterned semiconductor layer, a patterned insulation layer, and a patterned second conductor layer after forming the patterned first conductor layer, wherein the patterned insulation layer contacts with the patterned second conductor layer; and
forming a first permeation barrier layer which covers the patterned second conductor layer and the patterned insulation layer.

2. The method as claimed in claim 1, wherein the patterned semiconductor layer is formed before forming the patterned insulation layer which covers the patterned semiconductor layer, and the patterned insulation layer is formed before forming the patterned second conductor layer.

3. The method as claimed in claim 2, further comprising:
etching the patterned insulation layer to form a contact window which exposes part of the patterned first conductor layer.

4. The method as claimed in claim 3, further comprising:
etching the first permeation barrier layer formed to extend the contact window, wherein the contact window separates the first permeation barrier layer and the patterned insulation layer into a first region and a second region.

5. The method as claimed in claim 4, further comprising:
forming a patterned third conductor layer on surfaces of the contact window and the first permeation barrier layer after forming the contact window, wherein the patterned third conductor layer enters the contact window from the surface of the first permeation barrier layer.

6. The method as claimed in claim 5, further comprising:
disposing an isolation film layer on the substrate.

7. The method as claimed in claim 1, wherein the patterned insulation layer is formed before forming the patterned second conductor layer, the patterned semiconductor layer is formed after forming the patterned second conductor layer, and the patterned insulation layer covers the patterned first conductor layer.

8. The method as claimed in claim 7, further comprising:
etching the first permeation barrier layer to form a contact window which expose part of the patterned second conductor layer after forming the first permeation barrier layer.

9. The method as claimed in claim 8, further comprising:
forming a patterned third conductor layer on surfaces of the contact window and the first permeation barrier layer after forming the contact window, wherein the patterned third conductor layer enter the contact window from the surface of the first permeation barrier layer.

10. The method as claimed in claim 1, wherein the first permeation barrier layer is made of a multi-layers structure.

11. The method as claimed in claim 1, wherein the first permeation barrier layer is made of an organic and inorganic compound structure.

12. The method as claimed in claim 1, wherein a thickness of the first permeation barrier layer ranges from 1 nm to 100 nm, the Water Vapor Transmission Rate of the first permeation barrier layer ranges from 10E-2 g/m² day to 10E-6 g/m² day, and the Oxygen Transmission Rate of the first permeation barrier layer ranges from 10E-2 cc/m² day to 10E-5 cc/m² day.

13. The method as claimed in claim 1, wherein the first permeation barrier layer is made through a chemical vapor deposition process or a physical vapor deposition process.

14. The method as claimed in claim 1, wherein the first permeation barrier layer is made through a sheet to sheet process, a roll to roll process, or a reel to reel process.

15. A structure of a thin film transistor, comprising:
a patterned first conductor layer disposed on a substrate;
a patterned semiconductor layer, a patterned insulation layer, and a patterned second conductor layer disposed on the patterned first conductor layer, wherein the patterned insulation layer contacts with the patterned second conductor layer; and
a first permeation barrier layer covering the patterned second conductor layer and the patterned insulation layer.

16. The structure as claimed in claim 15, wherein the patterned semiconductor layer is the first, the patterned insulation layer is the second, and the patterned second conductor layer is the third to be disposed on the patterned first conductor layer, the patterned semiconductor layer contacts with the patterned first conductor layer, and the patterned insulation layer covers the patterned semiconductor layer.

17. The structure as claimed in claim 16, further comprising:
a contact window extended through the first permeation barrier layer and the patterned insulation layer to expose part of the patterned first conductor layer, wherein the contact window separates the first permeation barrier layer and the patterned insulation layer into a first region and a second region.

18. The structure as claimed in claim 17, further comprising:
a patterned third conductor layer entering the contact window from a surface of the first permeation barrier layer to contact with the first permeation barrier layer.

19. The structure as claimed in claim 18, further comprising:
an isolation film layer, disposed on the substrate, having a first surface in contact with the substrate and having a second surface which is back to the first surface in contact with the patterned first conductor layer.

20. The structure as claimed in claim 15, wherein the patterned insulation layer is the first, the patterned second conductor layer is the second, and the patterned semiconductor layer is the third to be disposed on the patterned first conductor layer, and the first permeation barrier layer covers the patterned insulation layer, the patterned second conductor layer, and the patterned semiconductor layer.

21. The structure as claimed in claim 20, further comprising:
a contact window extended through the first permeation barrier layer to expose part of the patterned second conductor layer.

22. The structure as claimed in claim 15, wherein the first permeation barrier layer is a multi-layers structure.

23. The structure as claimed in claim 15, wherein the first permeation barrier layer is an organic and inorganic compound structure.

24. The structure as claimed in claim 15, wherein a thickness of the first permeation barrier layer ranges from 1 nm to 100 nm, the Water Vapor Transmission Rate of the first permeation barrier layer ranges from 10E-2 g/m² day to 10E-6 g/m² day, and the Oxygen Transmission Rate of the first permeation barrier layer ranges from 10E-2 cc/m² day to 10E-5 cc/m² day.

25. An illuminating structure of a thin film transistor, comprising:
a patterned first conductor layer disposed on a substrate;
a patterned semiconductor layer, a patterned insulation layer, and a patterned second conductor layer disposed on the patterned first conductor layer, wherein the patterned insulation layer contacts with the patterned second conductor layer; and
a first permeation barrier layer covering the patterned second conductor layer and the patterned insulation layer, wherein the first permeation barrier layer is passed through by a contact window; and
an illuminating layer filled in the contact window.

26. The illuminating structure as claimed in claim 25, wherein the patterned semiconductor layer is the first, the patterned insulation layer is the second, and the patterned second conductor layer is the third to be disposed on the patterned first conductor layer, and the patterned semiconductor layer contact with the patterned first conductor layer and the patterned insulation layer covers the patterned semiconductor layer.

27. The illuminating structure as claimed in claim 26, wherein the contact window passes through only the first permeation barrier layer or passes through both the first permeation barrier layer and the patterned insulation layer.

28. The illuminating structure as claimed in claim 27, further comprising:
a patterned third conductor layer disposed on the illuminating layer; and
a second permeation barrier layer disposed on and covering the patterned third conductor layer.
